(19) United States
(12) Patent Application Publication
(10) Pub. No.: US 2025/0281925 A1
(43) Pub. Date: Sep. 11, 2025

(54) SEALING A MICROFLUIDIC MODULE BY MEANS OF SEALING FILM AND SEALING RIDGE

(71) Applicant: Hahn-Schickard-Gesellschaft für angewandte Forschung e.V., Villingen-Schwenningen (DE)

(72) Inventors: Raimund ROTHER, Grünstadt-Asselheim (DE); Martin MEYER, Freiburg (DE); Rouven STRELLER, Hinterzarten (DE); Markus ROMBACH, Freiburg (DE)

(21) Appl. No.: 19/220,401

(22) Filed: May 28, 2025

Related U.S. Application Data
(63) Continuation of application No. PCT/EP2023/081916, filed on Nov. 15, 2023.

(30) Foreign Application Priority Data
Nov. 29, 2022 (DE) 10 2022 212 821.4

(51) Int. Cl. B01L 3/00

(52) U.S. Cl. CPC B01L 3/502707; B01L 2200/028; B01L 2200/0689

(57) ABSTRACT

A method for producing a sealed microfluidic module which has a module body and a sealing film sealing a microfluidic cavity in a surface of the module body has providing the module body having the microfluidic cavity in a surface thereof and a sealing ridge at least partially surrounding the microfluidic cavity and projects from the surface, providing the sealing film having a sealing layer and an outer layer, the sealing layer having a softening temperature below a sealing temperature and the outer layer having a softening temperature above the sealing temperature, and sealing the microfluidic cavity with the sealing film by bringing the sealing layer of the sealing film into contact with the surface of the module body and applying temperature and pressure to heat the sealing layer to the sealing temperature and to produce an adhesive bond between the sealing film and the module body.

### CROSS-REFERENCES TO RELATED APPLICATIONS

This application is a continuation of copending International Application No. PCT/EP2023/081916, filed Nov. 15, 2023, which is incorporated herein by reference in its entirety, and additionally claims priority from German Application No. 10 2022 212 821.4, filed Nov. 29, 2022, which is also incorporated herein by reference in its entirety.

### TECHNICAL FIELD

The present invention relates to microfluidic modules and methods for producing microfluidic modules and, in particular, to microfluidic modules and methods for producing microfluidic modules comprising a seal between a sealing film and a sealing ridge.

### BACKGROUND OF THE INVENTION

Microfluidics is concerned with the behavior of fluids on small module bodies and is used, for example, in quick tests, lab-on-a-chip and small-space cell cultures. In this case, it may be necessary to seal a microfluidic cavity with a sealing film. This can be effected by, among other things, the aid of heat (thermal sealing). In the case of the thermal sealing of microfluidic components, unevenness in the one-digit to two-digit μm range can already result in air inclusions, capillary gaps or fluidic short circuits between structures on the one side or blockages of microfluidic cavities on the other side arising during the sealing process. Such defects may reduce the tightness or impair the functionality of fluidic structures in another way. The larger the sealing area, the higher the requirements to the evenness of the cartridge, that is the tool production for cartridge production since a locally too high sealing pressure applied to elevations can result in the sealing layer penetrating into the microfluidic channels (height differences). As a result, there is an increased risk for these channels being closed.

One approach for compensating for unevenness is the use of a sealing film with a height compensation layer.

FIG. 1A shows an example of a known microfluidic module 100′, comprising a module body 110′ and a sealing film 130′. The module body 110′ has a surface 114′ and a microfluidic cavity 112′. The sealing film 130′ has a sealing layer 132′, an outer layer 134′ and a height compensation layer 133′ and a barrier layer 135′ therebetween. The height compensation layer 133′ becomes soft during sealing and serves to compensate for unevenness of the surface 114′ to be sealed. The barrier layer 135′ remains solid during the sealing process and forms a shaping hard layer during sealing between the soft height compensation layer 133′ and the soft sealing layer 132′.

The surface 114′ has unevenness which is shown excessively large in FIG. 1A for reasons of visibility.

FIG. 1B shows the microfluidic module 100′ of FIG. 1A in the sealed state. During sealing, the sealing film 130′ is heated to a temperature at which the height compensation layer 133 and the sealing layer 132 become soft. The height compensation layer 133 (and to a smaller extent also the sealing layer 132) at least partially compensates for the unevenness of the surface 114′ in order to improve the sealing quality.

In the case of the microfluidic module 100′, however, uncontrolled air inclusions may occur with an increasing sealing area. Furthermore, a locally too high sealing pressure applied to elevations of the unevenness may result in the sealing layer penetrating into the microfluidic cavity 112′. In order to compensate for the differences in height of the unevenness, for example, a height compensation layer 133′ is required within the sealing film 130′, thereby increasing the complexity of the sealing film construction. This height compensation layer 133′ must become soft during sealing in order to perform this function and makes, for example, the barrier layer 135′ between the sealing layer 132′ and the height compensation layer 133′ necessary.

The ability of the sealing film 130′ to compensate for unevenness is limited. If the differences in height of the unevenness exceed the compensation capability of the sealing film 130′, regions of the sealing film 130′ in which there is no or reduced contact with the surface 114′ may arise between unevenness, which may result in a locally increased risk for too low sealing strength or bypasses, in particular if the defect occurs in the immediate vicinity of microfluidic structures. Furthermore, there is a risk of gas pressures arising during operation of the microfluidic module 100′ causing the (possibly thin and brittle) barrier layer 135′ to burst, and delamination occurring within the sealing film 130′ along the softened height compensation layer 133′. This risk is increased, in particular, at locations with too high a contact pressure (so-called pressure peaks) resulting from local unevenness.

Document DE 10 2018 217 907 B3 discloses a sealing film with a sealing layer, a height compensation layer, a decoupler layer and an outer layer.

Document DE 10 2016 222 028 A1 discloses a fluid chamber which is closed by a closure film with an initial crack region.

The object underlying the invention is improving the sealing, increasing a selection of compatible sealing films, reducing the dependence on the flatness of the surface of the microfluidic module 100′ or at least improving a compromise of these objects.

### SUMMARY

According to an embodiment, a method for producing a sealed microfluidic module which has a module body and a sealing film sealing a microfluidic cavity in a surface of the module body may have the steps of: providing the module body which has the microfluidic cavity in a surface thereof and a sealing ridge which at least partially surrounds the microfluidic cavity and projects from the surface; providing the sealing film which has a sealing layer and an outer layer, wherein the sealing layer has a softening temperature below a sealing temperature and the outer layer has a softening temperature above the sealing temperature; sealing the microfluidic cavity with the sealing film by bringing the sealing layer of the sealing film into contact with the surface of the module body and applying temperature and pressure in order to heat the sealing layer to the sealing temperature and to produce an adhesive bond between the sealing film and the module body.

According to another embodiment, a microfluidic module may have: a module body which has a microfluidic cavity in a surface thereof and a sealing ridge which at least partially surrounds the microfluidic cavity and projects from the surface; and a sealing film which is adhesively bonded with the module body and seals the microfluidic cavity, wherein the sealing film has a sealing layer and an outer layer, wherein the sealing layer has a softening temperature below a sealing temperature and the outer layer has a softening temperature above the sealing temperature, wherein the sealing ridge extends in the sealing layer and the sealing layer is in contact with regions of the surface of the module body outside the sealing ridge.

Examples provide a method for producing a sealed microfluidic module which comprises a module body and a sealing film sealing a microfluidic cavity in a surface of the module body. The method comprises providing the module body which has the microfluidic cavity in a surface thereof and a sealing ridge which at least partially surrounds the microfluidic cavity and projects from the surface, providing the sealing film which has a sealing layer and an outer layer, wherein the sealing layer has a softening temperature below a sealing temperature and the outer layer has a softening temperature above the sealing temperature. Furthermore, the method comprises sealing the microfluidic cavity with the sealing film by bringing the sealing layer of the sealing film into contact with the surface of the module body and applying temperature and pressure in order to heat the sealing layer to the sealing temperature and to produce an adhesive bond between the sealing film and the module body.

Examples provide a microfluidic module comprising a module body which has a microfluidic cavity in a surface thereof and a sealing ridge which at least partially surrounds the microfluidic cavity and projects from the surface, and a sealing film which is adhesively bonded with the module body and seals the microfluidic cavity. The sealing film has a sealing layer and an outer layer, wherein the sealing layer has a softening temperature below a sealing temperature and the outer layer has a softening temperature above the sealing temperature, wherein the sealing ridge is dipped in the sealing layer and the sealing layer is in contact with regions of the surface of the module body outside the sealing ridge.

### BRIEF DESCRIPTION OF THE DRAWINGS

Embodiments of the invention will be explained in greater detail below referring to the appended drawings, in which:

FIG. 1A is a schematic cross-section of an example of a known microfluidic module;

FIG. 1B is a schematic cross-section of the microfluidic module of FIG. 1A in the sealed state;

FIG. 2A is a schematic cross-section through an example of a microfluidic module;

FIG. 2B shows a schematic cross-section through an example of a microfluidic module with a sealing ridge with a cross-section in the form of a rectangular triangle;

FIG. 3A is a schematic cross-section of an example of a microfluidic cavity with a sealing ridge which is wider than high;

FIG. 3B is a schematic cross-section of an example of a sealing film;

FIG. 4A is a plan view of an example of a module body with a sealing ridge which completely frames the microfluidic cavity;

FIG. 4B is a plan view of an example of a module body with a sealing ridge which does not completely frame the microfluidic cavity;

FIG. 4C is a plan view of an example of a module body with a branched sealing ridge;

FIG. 5A shows a schematic plan view of an example of a microfluidic module with sealing ridges which have a constant cross-section at end sections;

FIG. 5B shows a schematic side view of the microfluidic module of FIG. 5A;

FIG. 5C shows a schematic plan view of an example of a microfluidic module with sealing ridges which are beveled at end sections;

FIG. 5D shows a schematic side view of the microfluidic module of FIG. 5C;

FIG. 6A is a schematic cross-section through an example of a microfluidic module in which the surface has a height offset;

FIG. 6B is a schematic cross-section through an example of a microfluidic module in which the surface exhibits a change of orientation;

FIG. 6C is a schematic cross-section through an example of a microfluidic module with two microfluidic cavities; and

FIG. 7 is a flow chart of a method for producing a sealed microfluidic module.

### DETAILED DESCRIPTION OF THE INVENTION

In the following, examples of the present disclosure will be described in detail and using the appended drawings. It is to be mentioned that same elements or elements having the same functionality are provided with the same or similar reference numerals, wherein a repeated description of elements provided with the same or similar reference numerals is typically omitted. In particular, same or similar elements may each be provided with reference numerals having a same number with a different or no lower case letter. Descriptions of elements having the same or similar reference numerals may be interchangeable with one another. In the following description, many details are described to provide a more thorough explanation of examples of the disclosure. However, it will be apparent to those skilled in the art that other examples may be implemented without these specific details. Features of the different described examples may be combined with one another, unless features of a corresponding combination are mutually exclusive or such a combination is explicitly excluded.

Before examples of the present disclosure are explained in greater detail, definitions of some terms used herein are provided.

The term sealing temperature is to be understood to mean a target temperature to which a sealing layer is heated in the sealing process.

The term softening temperature or glass transition temperature is to be understood herein to mean a temperature at which an amorphous plastic transitions from the glassy state to a viscoelastic state.

As will be apparent to those skilled in the art, the term liquid as used herein also includes, in particular, liquids containing solid constituents, such as suspensions, biological samples and reagents.

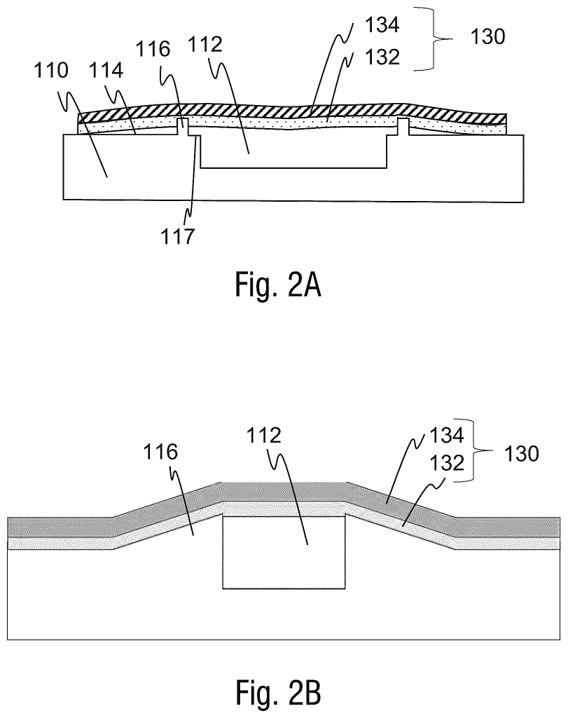

FIG. 2A shows a schematic cross-section through an example of a microfluidic module 100. The microfluidic module 100 comprises a module body 110 which has a microfluidic cavity 112 in a surface 114 thereof and a sealing ridge 116 which at least partially surrounds the microfluidic cavity 112 at a distance 117 and projects from the surface 114 (e.g. wherein the surface 114 surrounds the microfluidic cavity 112 and the sealing ridge 116, e.g. wherein the sealing ridge 116 is arranged laterally between the surface 114 and the microfluidic cavity 112). Furthermore, the microfluidic module 100 comprises a sealing film 130 which is adhesively bonded to the module body 110 and seals the microfluidic cavity 112. The sealing film 130 has a sealing layer 132 and an outer layer 134, wherein the sealing layer 132 has a softening temperature below a sealing temperature and the outer layer 134 has a softening temperature above the sealing temperature, wherein the sealing ridge 116 is dipped in the sealing layer 132 and the sealing layer 132 is in contact with regions of the surface 114 of the module body 110 outside the sealing ridge 116. Alternatively, the sealing film 130 may not be in contact with the surface 114 of the module body 110. The sealing film 130 may, for example, only be in contact with the sealing ridge 116.

It has been recognized that the sealing ridge 116 sealing by the sealing film 130 reduces a dependence of the sealing quality on the quality of the surface 114 of the module body 110. Consequently, requirements for production tolerances of the module bodies and a waste of module bodies 110 can be reduced. Furthermore, a sealing film 130 which does not have a compensation layer (and a barrier layer for the compensation layer) for compensating for differences in height of the surface can be used for sealing. Consequently, less complex sealing films 130 can be used or compatibility with different types of sealing films can be improved. Furthermore, the sealing becomes more time-efficient since process steps which are associated with a compensation layer can be dispensed with. Since the sealing is less dependent on the evenness of the surface 114, the sealing can be improved. The protruding of the sealing ridge 116 from the surface 114 makes it possible for the sealing ridge 116 to dip into the sealing layer 132 during the sealing process and consequently reduces the risk of air inclusions crossing the sealing ridge 116. However, it is not necessary to completely avoid air inclusions in order to obtain an improved sealing result. It may be sufficient for the risk of the air inclusions having contact with the microfluidic cavity 112 to be reduced. This risk is reduced by the sealing ridge 116 since the sealing ridge 116 improves a separation between the microfluidic cavity 112 and zones with potentially sealed-in air.

Furthermore, the integration of a sealing ridge 116 offers advantages when producing tools (for example for injection molding) since the entire surface 114 does not have to be located at a precisely identical level. Ensuring a precisely identical level is difficult to realize in terms of production technology due to tool wear and temperature fluctuations during machining. The influence of differences in height of the sealing area on the sealing quality can thus be reduced.

The sealing ridge 116 can be formed to be directly adjacent to the microfluidic cavity 112 and surrounding the same. Since the sealing ridge 116 is adjacent to the microfluidic cavity 112, the sealing film 130 extends primarily (or exclusively) over the microfluidic cavity 112 such that the microfluidic module 100 is formed to be compact. Since the sealing ridge 116 surrounds the microfluidic cavity 112, the improved sealing quality extends over the entire microfluidic cavity 112.

The sealing ridge 116 can be arranged to be flush with a wall of the microfluidic cavity 112. In other words, a wall of the microfluidic cavity 112 can transition into the sealing ridge 116 in a direction from the microfluidic cavity 112 toward the sealing film 130. Alternatively, the sealing ridge 116 can extend to be laterally offset to an edge of the microfluidic cavity 112 (as shown, for example, in FIG. 2A). As a result, a distance between the sealing areas is reduced such that the risk of the sealing film penetrating into the microfluidic cavity is reduced. The sealing ridge 116 can have a constant lateral offset 117 with respect to the edge of the microfluidic cavity 112. The lateral offset 117 can have a length between 100 μm and 1000 μm, e.g. 200 μm and 500 μm, e.g. 300 μm and 400 μm. The lateral offset 117 allows a more flexible design of an edge of the microfluidic cavity 112 (e.g. for an orientation of a wetting angle).

The sealing ridge 116 can have a width in a range from 50 μm to 2000 μm, e.g. 100 μm to 1000 μm, e.g. 200 μm to 500 μm. When the sealing layer 130 is pressed on, such a width results in a pressure which improves penetration of the sealing ridge 116 into the sealing film 130. The sealing ridge 116 can have a height in a range between 5 μm and 2000 μm (or a height greater than 2000 μm), e.g. 10 μm to 100 μm, e.g. 20 μm to 50 μm. Such a height allows penetration into the sealing layer 130 to a depth which allows improved sealing. The sealing ridge 116 can have a constant width and/or a constant height along its extension.

The width of the sealing ridge 116 can therefore be greater than the height. The ratio between width and height can be between 5:1 and 500:1.

The sealing ridge 116 can have a cross-section with a rectangular shape (e.g. an elongated rectangle or square). The sealing ridge 116 in FIG. 2A has, for example, a cross-section with an elongated rectangle. As a result, the sealing ridge has a large sealing area. Alternatively, the cross-section can have the shape of a trapezoid, a triangle (e.g. a rectangular triangle) or a segment of a circle. The rectangular or trapezoidal cross-sectional shape may have one or more rounded corners.

The microfluidic cavity 112 may have a bottom surface (e.g. arranged parallel to at least a part of the surface 114) which is arranged to be recessed, raised or in parallel with respect to the surface 114 (and thus also with respect to the sealing ridge 116).

FIG. 2B shows a schematic cross-section through an example of a microfluidic module 100 with a sealing ridge 116 with a cross-section in the form of a rectangular triangle. Consequently, the sealing ridge 116 has an oblique surface.

The sealing ridge 116 may have an asymmetrical shape. As a result, an asymmetrical displacement of the material of the softened sealing layer 132 can be realized. The sealing ridge 116 may, for example, have a cross-section with an asymmetrical trapezoid shape (e.g. a rectangular trapezoid). The side of the asymmetrical trapezoid with the more acute angle can point away from the microfluidic cavity 112. As a result, material of the softened sealing layer 132 is primarily displaced away from the microfluidic cavity 112.

The sealing ridge 116 may be formed to be integral with the remainder of the module body 110. Alternatively, the sealing ridge may be a separate component which is, for example, connected to the surface 114.

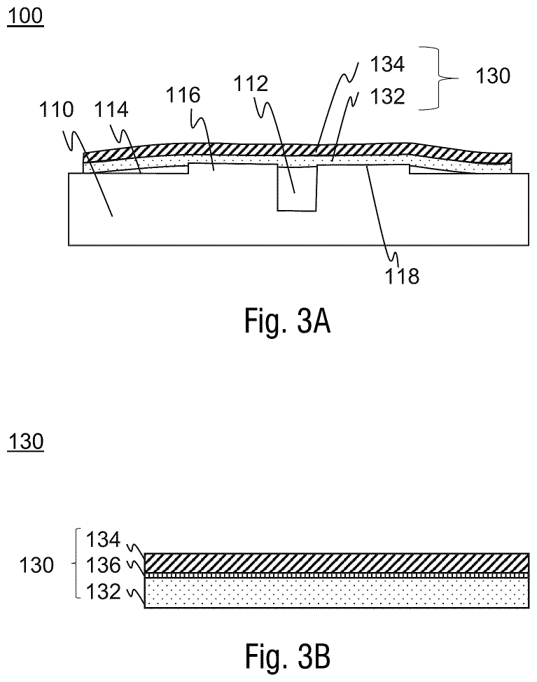

FIG. 3A shows a schematic cross-section of an example of a microfluidic cavity 112 with a sealing ridge 116 which is wider than high. In the example in FIG. 3A, the ratio between width and height is 10:1.

Furthermore, FIG. 3A shows an example of a sealing ridge 116 which is flush with a wall of the microfluidic cavity 112. In other words, a cavity-side side wall of the sealing ridge 116 is flush with a wall of the microfluidic cavity 112.

The sealing film 130 may have only an adhesion promotion layer between the sealing layer 132 and the outer layer 134, wherein the adhesion promotion layer advantageously has a thickness of less than 5 μm, e.g. less than 3 μm, e.g. less than 1 μm. Owing to the sealing ridge 116, successful sealing can also be effected on such an uneven surface which would entail a compensation layer in some cases. Such a compensation layer (and optionally a barrier layer for this) can therefore be dispensed with. Since the sealing film 130 in this case has only the sealing layer 132, the outer layer 134 and the adhesion promotion layer therebetween, the adhesion promotion layer is in direct contact with the sealing layer 132 and the outer layer 134.

FIG. 3B shows a schematic cross-section of an example of a sealing film 130 with an outer layer 134, a sealing layer 132 and an adhesion promotion layer 136 between the outer layer 134 and the sealing layer 132. The adhesion promotion layer 136 allows adhesion between the sealing layer 132 and the outer layer 134. The adhesion promotion layer 136 can therefore be directly adjacent to the sealing layer 132 and the outer layer 134 such that no further layer is arranged between the adhesion promotion layer 136 and the sealing layer 132 and the outer layer 134. The sealing film 130 can be produced more favorably due to the smaller number of layers. The sealing film 130 can thereby also be formed to be thinner. Consequently, a temperature input through the sealing film 130 into the microfluidic cavity 112 can be effected more rapidly such that samples in the microfluidic cavity 112 can be processed in a more time-efficient manner. A thinner film has better transparency and thus improves optical evaluation by a user or an optical measuring device (e.g. due to an improved measuring path between signal generation and detection).

The sealing layer 132 of the sealing film 130 can optionally be designed to be thicker and thus assume the compensating function of the non-existent height compensation layer to a greater extent since the risk of the sealing layer 132 being pressed into the microfluidic cavity 112 can also be minimized by the sealing pressure reduction described above.

The outer layer 134 can comprise a polymer (e.g. polycarbonates). The outer layer 134 may comprise or be a biaxially oriented polyester film (BoPET). The outer layer 134 thus has a high tensile strength. The outer layer 134 may also comprise or be formed from other plastics with high tensile strength.

The outer layer 134 can have a layer thickness between 2 μm and 100 μm, e.g. between 5 μm and 50 μm, e.g. between 10 μm and 30 μm. The outer layer 134 can be formed to stabilize the sealing film 130 (e.g. during sealing) and can reduce or prevent penetration of the sealing film 130 into the microfluidic cavity 112. Furthermore, the outer layer 134 reduces adhesion of the sealing film 130 to a sealing plate which is configured to press the sealing film 130 onto the module body 110. In addition, the outer layer 134 reduces the risk of unintentional perforation of the sealing film 130.

The adhesion promotion layer 136 may comprise a polymer. The adhesion promotion layer 136 may comprise polyurethanes (PUR) or consist of PUR. PURs exhibit good adhesion properties and thus increase adhesion between the outer layer 134 and the sealing layer 132. The adhesion promotion layer 136 may also comprise other plastics and/or adhesive. The adhesion promotion layer 136 may have a layer thickness of less than 5 μm, e.g. less than 3 μm, e.g. less than 1 μm. Alternatively, the sealing film 130 may not have an adhesion promotion layer 136. The sealing film 130 may consequently have a sealing layer 132 which is connected directly (i.e. without intermediate layers) to the outer layer 134. The sealing film may consequently contain only an outer layer 134 and a sealing layer 132.

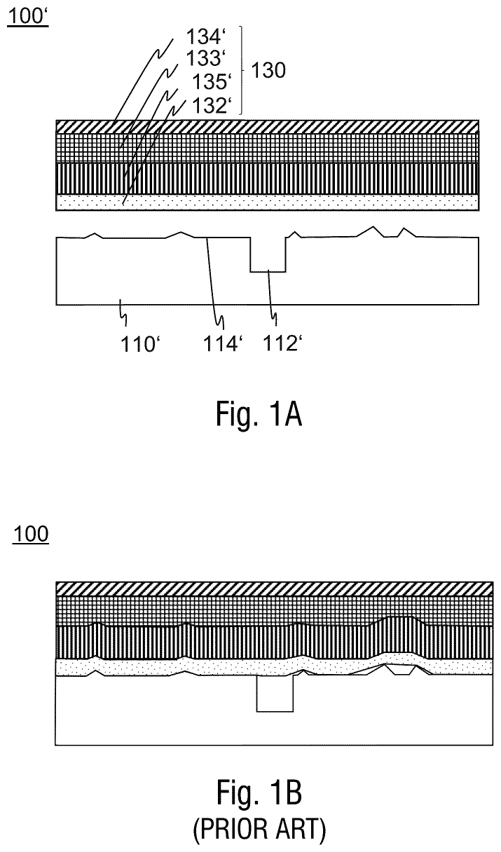

Since the sealing is less dependent on the evenness of the surface 114, instead of a height compensation layer, the adhesion promotion layer 136 may be provided, which may have a significantly thinner (˜2 μm) layer thickness and/or may be formed with increased strength. Furthermore, due to the adhesion promotion layer 136, for example, the barrier layer 135′ (see FIGS. 1A, B) can be dispensed with. As a result, the risk of breakthrough between the sealing film layers and thus bursting of the sealing film 130 is minimized in the sealing film 130. By omitting the barrier layer 135′, the number of film layers can be reduced. As a result, the sealing film 130 as a whole becomes thinner and the construction less complex. In addition to more cost-effective production, the heat conduction through the sealing film 130 is thus additionally improved, which significantly shortens process times in use. At the same time, the production of the sealing film 130 becomes easier and less susceptible to faults.

The sealing layer may comprise a polymer (e.g. polyurethanes). The sealing layer 132 may comprise cycloolefin copolymers (COCs) or consist of COCs. COC (e.g. COC 8007) exhibits good thermoplastic flowability. As a result, the sealing ridge 116 (above the softening temperature of the sealing layer 132) can dip deep into the sealing layer 132 and realize improved sealing. Furthermore, COCs usually have a softening temperature below the softening temperature of BoPET. Thus, for example, the softening temperature of COC 8007 is about 80° C.

The sealing layer 132 may have a layer thickness of between 3 μm and 200 μm, e.g. between 5 μm and 50 μm, e.g. between 10 μm and 30 μm.

The sealing film 130 may have a layer thickness between 5 μm and 500 μm, e.g. between 10 μm and 100 μm, e.g. between 20 μm and 50 μm.

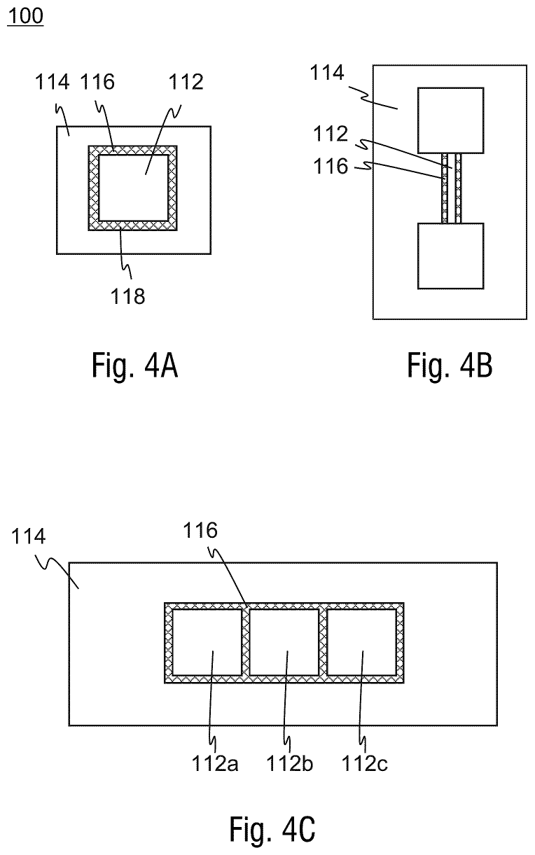

FIG. 4A shows a plan view of an example of a module body 110 with a sealing ridge 116 which completely frames the microfluidic cavity 112. Consequently, the microfluidic cavity 112 is completely sealed when sealed with the sealing film 130 (not shown in FIG. 4A). In FIG. 4A, a single microfluidic cavity 112 framed with a sealing ridge 116 is shown. However, the module body may also have two, three, four or more microfluidic cavities 112, wherein one or more of the microfluidic cavities 112 may each have a framing sealing ridge 116.

Alternatively, the sealing ridge 116 may only partially frame the microfluidic cavity 112. This may allow a fluid connection to the microfluidic cavity 112. This may, for example, be used for gas discharge in order to avoid an overpressure or exhaust gases of solvent. Furthermore, the microfluidic cavity 112 may have an unsealed liquid connection to a further microfluidic cavity 112.

FIG. 4B shows a plan view of an example of a module body 110 with a sealing ridge 116 which does not completely frame the microfluidic cavity 112. The microfluidic cavity 112 in FIG. 4B forms a fluid connection between two components of the module body 110 (e.g. further microfluidic cavities or fluid sensors). Alternatively, the sealing ridge 116 may completely frame the fluid connection and the two components.

FIG. 4C shows a plan view of an example of a module body 110 with a branched sealing ridge 116 which frames several microfluidic cavities 112a, b, c (at least partially or completely). The sealing ridge 116 may consequently comprise a multitude of frames connected to one another.

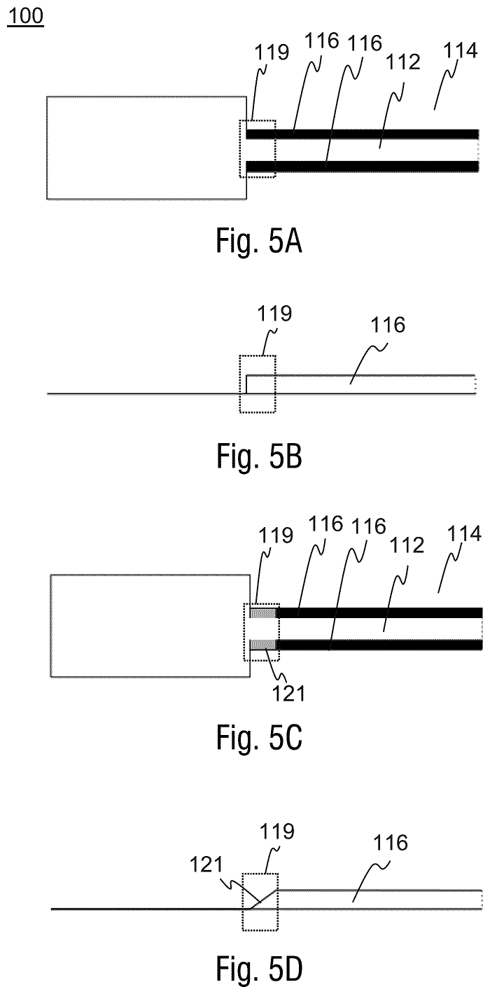

FIG. 5A shows a schematic plan view of an example of a microfluidic module 100 with sealing ridges 116 which have a constant cross-section at end sections 119. In the example of FIG. 5A, the sealing ridges 116 have a rectangular cross-section. In the end sections 119 (indicated in FIG. 5A by a dashed frame), the sealing ridges 116 have a constant cross-section.

FIG. 5B shows a schematic side view of the microfluidic module 100 of FIG. 5A. Since the sealing ridges 116 have a constant cross-section in the end sections, a surface of the sealing ridges facing away from the surface 114 is parallel to the surface 114.

FIG. 5C shows a schematic plan view of an example of a microfluidic module 100 with sealing ridges 116 which are beveled 121 (e.g. have a decreasing elevation) at end sections 119.

FIG. 5D shows a schematic side view of the microfluidic module 100 of FIG. 5C. The beveling of the sealing ridge 116 allows a better transition from the sealing ridge 116 to the surface 114. The beveling of the sealing ridge 116 reduces the risk of unintentional bypasses.

The microfluidic module 100 of FIGS. 5A, B has two sealing ridges 116 each with a bevel 121. Alternatively, the microfluidic module 100 may have a different number of sealing ridges 116, of which any number of sealing ridges 116 may have one or more bevels 121 (e.g. at both ends each).

The sealing ridge 116 comprises a sealing area 118 which can be arranged in a common imaginary plane. The sealing area 118 may extend at least substantially parallel to the surface 114.

The module body 110 may comprise several surfaces 114, wherein at least two of the surfaces 114 differ in their orientation and/or height offset since the sealing can be carried out completely or at least largely completely due to the sealing ridges 116.

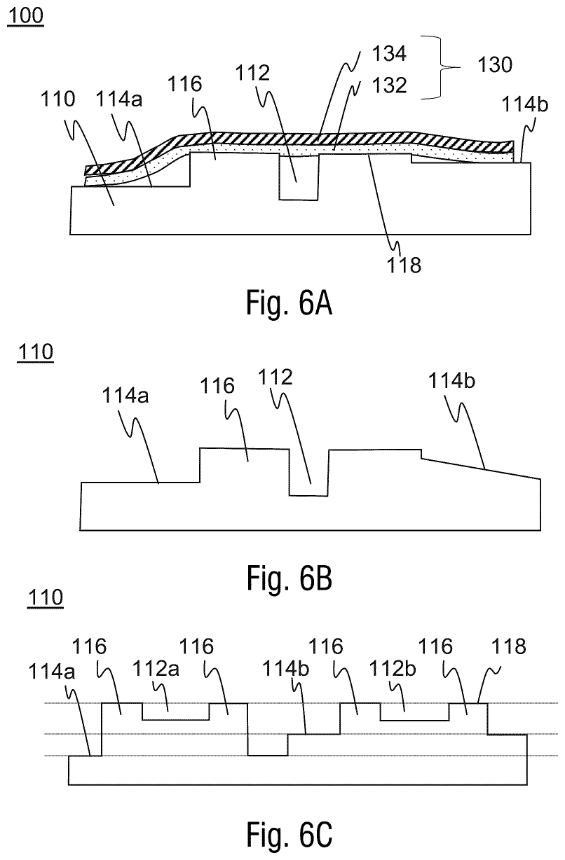

FIG. 6A shows a schematic cross-section through an example of a microfluidic module 100 in which the surface 114 has a height offset. The surface 114 comprises a first surface part 114a and a second surface part 114b, wherein the first and the second surface part 114a, b have a height offset in a direction perpendicular to the imaginary plane of the sealing area 118.

FIG. 6B shows a schematic cross-section through an example of a microfluidic module 100 in which the surface 114 exhibits a change in orientation. The surface 114 comprises a first surface part 114a and a second surface part 114b, wherein the first and the second surface part 114a, b have two different orientations (e.g. different normal vectors).

FIG. 6C shows a schematic cross-section through an example of a microfluidic module 100 with two microfluidic cavities 112a, b. Both microfluidic cavities 112a, b have a sealing ridge 116, wherein the two sealing ridges have a sealing area 118 arranged in a common imaginary plane. A first microfluidic cavity 112a is surrounded by a first surface part 114a and a second microfluidic cavity 112b is surrounded by a second surface part 114b. The two surfaces 114a, b have a surface offset. In other words, the first surface part 114a has a different distance from the imaginary plane of the sealing ridge 116 than the second surface part 114b.

The sealing ridges 116 reduce the dependence of the sealing on the surfaces 114. Consequently, a sealing ridge 116 not only allows improved sealing in the case of uneven surfaces 114 but also improved sealing in the case of an offset of surfaces 114 and/or different orientations of surfaces 114.

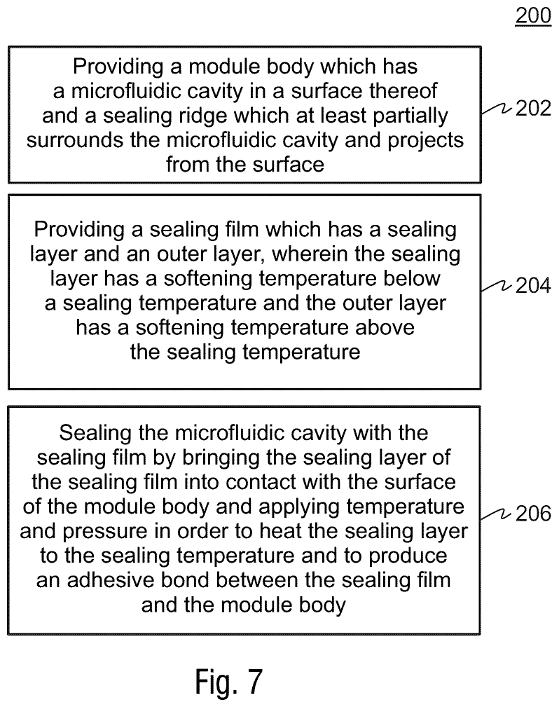

FIG. 7 shows a flow chart 200 of a method for producing a sealed microfluidic module 100 as described herein.

The method comprises, in step 202, providing the module body 110 which has the microfluidic cavity 112 in the surface 114 thereof and the sealing ridge 116 which at least partially surrounds the microfluidic cavity 112 and projects from the surface 114.

The method further comprises, in step 204, providing the sealing film 130 which has the sealing layer 132 and the outer layer 134, wherein the sealing layer 132 has a softening temperature below a sealing temperature and the outer layer 134 has a softening temperature above the sealing temperature.

The method comprises, in step 206, sealing the microfluidic cavity 112 with the sealing film 130 by bringing the sealing layer 132 of the sealing film 130 into contact with the surface 114 (e.g. into contact at least with the sealing ridge 116 and optionally with a region of the surface 114 which surrounds the sealing ridge 116) of the module body 110 and applying temperature and pressure in order to heat the sealing layer 132 to the sealing temperature and to produce an adhesive bond between the sealing film 130 and the module body 110.

It has been recognized that the sealing ridge 116 can be formed independently of an unevenness of the surface 116. As a result, the sealing ridge 116 can be used as a surface for reliable sealing.

When the microfluidic cavity 112 is sealed with the sealing film 130, such a pressure can be applied that the sealing ridge 116 dips into the sealing layer 132 and the sealing layer 132 comes into contact with regions of the surface 114 outside the sealing ridge 116.

It has been recognized that, during a sealing process, at first the sealing ridge 116 and only then the surface 114 comes into contact with the sealing film 130. Since the sealing ridge 116 alone has a smaller area than together with the surface 114, when a (for example constant) sealing force is applied, the pressure which the sealing ridge 116 exerts on the sealing film 130 is greater than the pressure which the surface 114 and the sealing ridge 116 exert together on the sealing area 130. Therefore, the pressure on the sealing film 130 decreases significantly as soon as the sealing film 130 comes into contact with the surface 116. More precisely, a sealing pressure decreases automatically by a factor a=A_{ST}/(A_{O}+A_{ST}) with a sealing surface A_{ST} of the sealing ridge and a sealing surface A_{O} of the surface 114. In this context, a sealing surface is an area of the module body 110 which comes into contact with the sealing film 130 or is sealed with it. Due to the reduction of the sealing pressure on contact with the regions of the surface 114, the sealing film 130 and the module body 110 are pressed together less strongly (or not further). As a result, above all the risk of the sealing layer 132 penetrating into the microfluidic cavity 112 is reduced.

Sealing the microfluidic cavity 112 can comprise heating at least one of the module body 110, the sealing film 130 and an ambient atmosphere to the sealing temperature. Since the sealing temperature is between the softening temperatures of the sealing layer 132 and the outer layer 134, the sealing layer is (at least substantially) softened and the outer layer 134 remains (at least substantially) solid. Consequently, the sealing ridge can penetrate into the softened sealing layer 132 but not into the outer layer 134.

The method can comprise clipping excess sealing film 130. The clipping can comprise cutting and/or melting through the sealing film 130. Cutting and/or melting through can be effected beyond a contact surface between the sealing film 130 and the surface 114 such that the sealing film 130 contacts both the sealing ridge 116 and the surface 114. Alternatively, cutting and/or melting through can be effected between the sealing ridge 116 and the surface 114 such that (after removal of the excess sealing film 130 beyond a cutting or melting edge) the sealing film 130 contacts the sealing ridge 116 but not the surface 114. Cutting and/or melting through can be effected by means of at least one of a cutting edge, a heated melting element and a laser.

Providing the module body 110 can comprise an injection molding method and/or an additive method (e.g. 3D printing). The injection molding method can comprise injecting a plastic into a milled metal mold. The metal mold can be produced by means of a computerized numerical control (CNC) milling machine. Since the sealing quality is less dependent on the surface 114 due to the sealing ridge 116, the requirements to the injection molding method and/or the additive method are lower.

Although features of the invention have been described on the basis of device features or method features, it will be apparent to those skilled in the art that corresponding features may also be part of a method or a device. Thus, the device can be configured to perform corresponding method steps and the respective functionality of the device can represent corresponding method steps.

In the preceding detailed description, partly different features have been grouped together in examples in order to rationalize the disclosure. This type of disclosure is not to be interpreted as intending that the claimed examples have more features than are explicitly cited in each claim. Rather, as the following claims reflect, the subject-matter may be less than all the features of a single disclosed example. Consequently, the following claims are hereby incorporated into the detailed description, where each claim may stand as its own separate example. While each claim may stand as its own separate example, it is to be noted that although dependent claims in the claims refer back to a specific combination with one or more other claims, other examples also comprise a combination of dependent claims with the subject-matter of any other dependent claim or a combination of any feature with other dependent or independent claims. Such combinations are to be included, unless it is stated that a specific combination is not intended. Furthermore, it is intended that a combination of features of a claim with any other independent claim is also included, even if this claim is not directly dependent on the independent claim.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A method for producing a sealed microfluidic module which comprises a module body and a sealing film sealing a microfluidic cavity in a surface of the module body, comprising:
providing the module body which comprises the microfluidic cavity in a surface thereof and a sealing ridge which at least partially surrounds the microfluidic cavity and projects from the surface;
providing the sealing film which comprises a sealing layer and an outer layer, wherein the sealing layer comprises a softening temperature below a sealing temperature and the outer layer comprises a softening temperature above the sealing temperature;
sealing the microfluidic cavity with the sealing film by bringing the sealing layer of the sealing film into contact with the surface of the module body and applying temperature and pressure in order to heat the sealing layer to the sealing temperature and to produce an adhesive bond between the sealing film and the module body.

2. The method according to claim 1, wherein the sealing ridge is formed to be directly adjacent to the microfluidic cavity and surrounding the same.

3. The method according to claim 1, wherein the sealing ridge comprises a width in a range from 50 μm to 2000 μm.

4. The method according to claim 1, wherein the sealing ridge comprises a height in a range between 5 μm and 200 μm.

5. The method according to claim 1, wherein, in order to seal the microfluidic cavity with the sealing film, such a pressure is applied that the sealing ridge dips into the sealing layer and the sealing layer comes into contact with regions of the surface outside the sealing ridge.

6. The method according to claim 1, wherein a sealing film is used in which only an adhesion promotion layer is provided between the sealing layer and the outer layer, wherein the adhesion promotion layer advantageously comprises a thickness of less than 5 μm.

7. The method according to claim 1, wherein a sealing plate is used in order to apply the temperature and the pressure for sealing the microfluidic cavity.

8. A microfluidic module comprising:
a module body which comprises a microfluidic cavity in a surface thereof and a sealing ridge which at least partially surrounds the microfluidic cavity and projects from the surface;
a sealing film which is adhesively bonded with the module body and seals the microfluidic cavity,
wherein the sealing film comprises a sealing layer and an outer layer, wherein the sealing layer comprises a softening temperature below a sealing temperature and the outer layer comprises a softening temperature above the sealing temperature, wherein the sealing ridge extends in the sealing layer and the sealing layer is in contact with regions of the surface of the module body outside the sealing ridge.

9. The microfluidic module according to claim 8, wherein the sealing ridge is formed to be directly adjacent to the microfluidic cavity and surrounding the same.

10. The microfluidic module according to claim 8, wherein the sealing ridge comprises a width in a range from 50 μm to 2000 μm and/or wherein the sealing ridge comprises a height in a range between 5 μm and 200 μm.

11. The microfluidic module according to claim 8, wherein the sealing film comprises only an adhesion promotion layer provided between the sealing layer and the outer layer, wherein the adhesion promotion layer advantageously comprises a thickness of less than 5 μm.
